(19) United States
(12) Patent Application Publication
(10) Pub. No.: US 2024/0100964 A1
(43) Pub. Date: Mar. 28, 2024

(54) INVERTER DEVICE AND ELECTRIC DRIVE ARRANGMENT

(71) Applicant: Schaeffler Technologies AG & Co. KG, Herzogenaurach (DE)

(72) Inventors: Julian Körner, Karlsruhe (DE); Eduard Enderle, Gengenbach (DE); Huan Fu, Rastatt (DE); Jürgen Tipper, Gernsbach (DE); Michael Reuschel, Ottersweier (DE); Thorsten Rittgerott, Offenburg (DE)

(73) Assignee: Schaeffler Technologies AG & Co. KG, Herzogenaurach (DE)

(21) Appl. No.: 18/275,624

(22) PCT Filed: Jan. 31, 2022
(86) PCT No.: PCT/DE2022/100081

§ 371 Date: Aug. 3, 2023

(30) Foreign Application Priority Data
Feb. 9, 2021 (DE) 10 2021 103 023.4

(51) Int. Cl. B60L 50/51; H02M 1/32; H02M 7/5387; H02P 27/06

(52) U.S. Cl. CPC B60L 50/51; H02M 1/322; H02M 7/53871; H02P 27/06; B60L 2210/42

(57) ABSTRACT

An inverter device includes a connection device and a housing in which an inverter circuit, a switching device and a control device are accommodated. The inverter circuit is connected to a direct current (DC) circuit and to an electric machine via the connection device, and the switching device is connected to the DC circuit and to resistor via the connection device. The inverter circuit is actuated by the control device to operate the electric machine, and the switching device is actuated by the control device to selectively energize one of the resistor or the DC circuit via the inverter circuit.

### CROSS-REFERENCE TO RELATED APPLICATIONS

This application is the U.S. National Phase of PCT Appln. No. PCT/DE2022/100081 filed Jan. 31, 2022, which claims priority to DE 102021103023.4 filed Feb. 9, 2021, the entire disclosures of which are incorporated by reference herein.

### TECHNICAL FIELD

The present disclosure relates to an inverter device comprising a connection device and a housing. The present disclosure further relates to an electric drive arrangement.

### BACKGROUND

In addition to an electric motor, electric drive trains of motor vehicles generally comprise an inverter to energize the electric motor. For this purpose, the inverter can be connected to an energy store designed, for example, as a traction battery, and can convert a direct current taken from the energy store into an alternating current for energizing the electric machine. Conversely, an alternating current generated in generator operation of the electric machine can also be converted via the inverter into direct current so that this can be fed back to the electrical energy store in a recuperation operation. Such a recuperation operation can be carried out, for example, when a motor vehicle comprising the drive train brakes or drives downhill, wherein the kinetic energy to be dissipated in the process is converted into electrical energy.

However, for example when driving downhill for a long time, it can happen that the electrical energy store is already fully charged. In such cases, the use of a brake chopper is known, which is designed to reduce electrical energy generated by the electric machine. With such a brake chopper, the electrical energy store and/or an intermediate circuit capacitor that can be present in the battery circuit can be protected against overcharging. This brake chopper represents a separate structural unit which, in addition to the inverter, takes up space in the motor vehicle and requires connections to other components and requires its own control unit.

### SUMMARY

The present disclosure is therefore based on specifying an improved inverter device which, in particular, has a simplified structure.

To solve this problem, in an inverter device of the type mentioned at the outset, the present disclosure, according to one exemplary embodiment, provides that an inverter circuit, a switching device, and a control device are accommodated in a housing of the inverter device, wherein the inverter circuit is able to be connected to a direct current (DC) circuit and to an electric machine via a connection device, and the switching device can be connected to the DC circuit and to at least one resistor via the connection device, wherein the inverter circuit is able to be activated by the control device for operating the electric machine, and the switching device is able to be activated by the control device for energizing the resistor from the DC circuit and/or via the inverter circuit.

An electric machine connected to the inverter device can be operated as a motor via the DC circuit when the inverter device is connected to the DC circuit or, in generator operation, can feed current into the DC circuit via the inverter device. The inverter circuit of the inverter device can convert a direct current taken from the DC circuit into an alternating current for motor operation of the electric machine, or convert an alternating current generated by the electric machine into a direct current. The connection device of the inverter device can, for example, be integrated into the housing and allow for the components arranged within the housing of the inverter device to be connected with the electric machine, the DC circuit, and/or the resistor. In this case, an alternating current (AC) side of the inverter circuit can be connected to the electric machine via a single-phase or multi-phase connection. When the DC circuit is connected to the inverter device, in particular, a DC side of the inverter circuit is connected to the DC circuit or integrated into the DC circuit so that energy can be released into the DC circuit via the inverter circuit when the electric machine is in generator operation.

The switching device of the inverter device, which can be connected to one or more resistors and the DC circuit via the connection device, can be used in generator operation of the electric machine to destroy electrical energy generated in the electric machine in a targeted manner. For this purpose, the resistor can be connected in parallel to the DC side of the inverter circuit via the switching device. As a result, the electrical energy can be supplied to the at least one resistor via the switching device to prevent the DC circuit from being overloaded. In this case, in particular, it is possible to prevent an overload of an energy store and/or an intermediate circuit capacitor which are arranged in the DC circuit or connected to the DC circuit. The intermediate circuit capacitor can be designed as a component of the DC circuit that can be connected to the inverter device, or it can be a component that is also arranged inside the housing of the inverter device and is connected, for example, to the DC side of the inverter.

To operate the electric machine in motor mode and/or during generator operation, the inverter circuit can be controlled via the control device. The switching device can also be controlled by the control device for energizing the resistor from the DC circuit. In this case, in particular, the resistor can be supplied with energy which is generated in the electric machine in generator operation and is converted via the inverter circuit into a direct current which is fed into the DC circuit.

The inverter device according to the present disclosure has the advantage that a common control device can be used both for operating the inverter circuit and for operating the switching device. This reduces the number of components required, particularly when the inverter device is used as part of an electric drive train. Installation space can advantageously be saved in this way. The use of a common control device for the inverter circuit and the switching device also has the advantage that the number of required interfaces and/or connecting means, which have to be arranged between the different components of an electric drive train, can be reduced. Furthermore, the use of a common control device simplifies the execution of tests in a test procedure since only a single control device needs to be checked. This also advantageously not only reduces the complexity but also the expenditures on manufacturing and testing the inverter device or an electric drive arrangement comprising the inverter device.

According to the present disclosure, the control device can be configured to activate the switching device for energizing the resistor in a brake chopper mode. In brake chopper operation, the switching device can be opened and closed in quick succession as specified by the control device, wherein electrical energy is conducted into the resistor when the switching device is closed and is converted into heat. In this way, an energy store and/or an intermediate circuit capacitor in the DC circuit can be discharged or electrical energy generated by the electric machine and no longer absorbable by the DC circuit can be consumed in the resistor.

The resistor is designed in particular to dissipate high electrical power so that in particular all of the energy that can be fed back via the electric machine can be converted into heat in the resistor. To operate the switching device, the control device can, for example, carry out an open-loop control method or a closed-loop control method with which the operation of the switching device and thus the electrical power supplied to the resistor can be specified.

In embodiments of the present disclosure, the control device can have a first driver circuit for actuating the inverter circuit, a second driver circuit for actuating the switching device, and a control unit, wherein the control unit is configured for actuating the first driver circuit and the second driver circuit. The switching elements of the inverter circuit, for example, the transistors of the half-bridges forming the inverter circuit, can be driven by the first driver circuit of the control device. Correspondingly, the switching device, which can connect the DC circuit to the resistor, can be controlled by the second driver circuit. Both the first driver circuit and the second driver circuit can be operated by the control unit of the control device so that the same control unit can advantageously be used for the operation of the switching device as for the operation of the first driver circuit. This advantageously reduces the complexity and the outlay in the production of the inverter device.

According to the present disclosure the first driver circuit, the second driver circuit and the control unit can be arranged on a common printed circuit board. The control device can thus be provided as a single component, which is implemented on a printed circuit board. As a result, the complexity involved in producing the inverter device can advantageously be reduced since fewer interfaces and fewer connecting means are required, which have to be arranged between the interfaces of different components.

Alternatively, according to the present disclosure, the first driver circuit and the control unit can be arranged on a first printed circuit board and the second driver circuit can be arranged on a second printed circuit board, wherein the first circuit board and the second printed circuit board are connected. The connection between the first printed circuit board and the second printed circuit board can be made in particular via a plug connection and/or via cables arranged between the first printed circuit board and the second printed circuit board. The first printed circuit board and the second printed circuit board are in particular mechanically and electrically connected to one another. A modular design of the control device is achieved in this way in which, in addition to the first driver circuit and the control unit which are used to operate the inverter circuit, the second printed circuit board with the second driver circuit can be added to also enable a control of the switching device of the inverter device. When the second printed circuit board is connected to the first printed circuit board, the control unit on the first printed circuit board and the second driver circuit on the second printed circuit board are electrically connected so that in particular the second driver circuit can be operated via the control unit.

According to the present disclosure, the switching device can be connected to a single-phase and/or a multi-phase resistor via the connection device. A single-phase resistor can have two terminals, which can be connected to the switching device via the connection device. An ohmic resistor formed from one or more resistance elements is arranged between the terminals of the resistor, which can thus be connected via the switching device to the DC circuit and in particular in parallel to an energy storage device arranged in the DC circuit.

In the case of a multi-phase resistor, it can have more than two terminals, for example two end terminals and at least one, in particular asymmetrical, center tap so that different resistance values can be tapped between the various terminals of the resistor. These different resistance values can be connected individually and/or in parallel or in series to the DC circuit or connected in parallel to an energy store arranged in the DC circuit by connecting the three or more terminals via the connecting device to the switching device. In this way, electrical power to be dissipated can be destroyed via different resistance values of the resistor.

In embodiments of the present disclosure, the switching device can have at least one power switching element, in particular a bipolar transistor having an insulating gate or a metal oxide semiconductor field-effect transistor. The power switching element can be made based on silicon carbide. This advantageously enables high power to be switched so that even in the case of powerful electric machines, electrical energy generated can be dissipated via the switching device and the resistor.

Provision can be made according to the present disclosure for the switching device to have multiple power switching elements, wherein the power switching elements form at least one half-bridge and/or at least one full-bridge. The use of multiple power switching elements can be used to improve the reliability of the switching device and thus advantageously to prevent an unintentional energization of the resistor. In the case of a switching device designed as a half-bridge, the resistor can be arranged between the high-side switch and the low-side switch, for example. In the case of a switching device designed as a full-bridge, the resistor can be switched into the bridge branch or, in the case of a multi-phase resistor, different terminals can be connected to the respective bridge points of the half-bridges.

The use of a switching device designed as a half-bridge or as a full-bridge has the advantage that the inverter circuit in particular can also comprise one or more half-bridges and/or full-bridges so that switching devices of the same design can be used, for example, which further simplifies the arrangement of the inverter circuit and the switching device in the housing. It is possible for the power switching elements of the switching device to comprise freewheeling diodes and/or for a diode to be connected in series with a resistor that can be switched via the switching device to establish an individual current direction.

According to the present disclosure, the inverter circuit and the switching device can be arranged together on a housing side of the housing and/or on a common cooling device. The cooling device can, for example, be a passive heat sink such as a heat conducting sheet or the like. This advantageously allows the inverter circuit and the switching device or the respective switching elements of the inverter circuit and the switching device to be cooled together via the housing side of the housing and/or via the common cooling device. For this purpose, the inverter device can be connected to a cooling circuit, for example, so that heat absorbed from the switching elements via the housing side or via the cooling device can be dissipated to a cooling device. The joint cooling of the switching elements of the inverter circuit and the switching device contributes to a compact construction of the inverter device and particularly advantageously reduces the installation space required for the inverter device in a motor vehicle.

For an electric drive arrangement, it is provided according to the present disclosure that it has the inverter device according to the present disclosure, an electric machine, a resistor and a DC circuit comprising electrical energy storage. The DC circuit can also have an intermediate circuit capacitor. In this case, the intermediate circuit capacitor can be arranged outside the housing of the inverter device or inside the housing of the inverter device.

All the advantages and configurations described above in relation to the inverter device according to the present disclosure apply correspondingly to the electric drive arrangement according to the present disclosure and vice versa.

### BRIEF DESCRIPTION OF THE DRAWINGS

The present disclosure is explained below on the basis of exemplary embodiments with reference to the drawings. The drawings are schematic representations, wherein:

FIG. 1 shows an exemplary embodiment of an electric drive arrangement according to the present disclosure,

FIG. 2 shows an exemplary embodiment of an inverter device according to the present disclosure, and

FIG. 3 shows a second exemplary embodiment of an inverter device according to the present disclosure.

### DETAILED DESCRIPTION

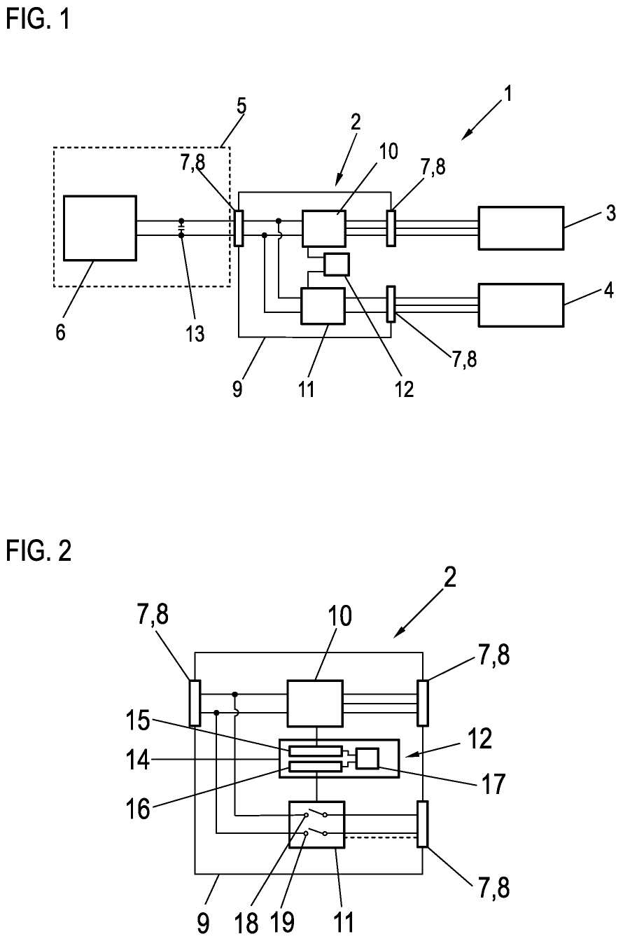

FIG. 1 shows an exemplary embodiment of the design of an electric drive arrangement 1. The electric drive arrangement 1 can be used, for example, in an electric vehicle, in particular in a passenger car, a truck, or a bus, for a purely electric drive or in combination with an internal combustion engine. The electric drive arrangement 1 comprises an inverter device 2, an electric machine 3, a resistor 4 and a DC circuit 5, which comprises an electrical energy store 6. The inverter device 2 comprises a connection device 7, which comprises multiple terminals 8 and a housing 9. The terminals 8 of the connection device 7 can be arranged on the housing 9, for example, to enable the connection of the inverter device 1 to the electric machine 3, the resistor 4, and the DC circuit 5.

The inverter device 2 also comprises an inverter circuit 10, a switching device 11, and a control device 12, which are arranged inside the housing 9. A direct current, which is taken from the DC circuit 5, can be converted via the inverter circuit 10 into an alternating current for motor operation of the electric machine 3. Furthermore, when the electric machine 3 is in generator operation, the inverter circuit 10 can convert an alternating current generated by the electric machine 3 into a direct current, which can be supplied to the DC circuit 5 and in particular to the electrical energy store 6. For this purpose, a DC side of the inverter circuit 10 is connected to the DC circuit 5 or integrated into the DC circuit 5. An AC side of the inverter circuit 10 is connected to the electric machine 3 via a three-phase connection, for example.

To prevent electrical energy store 6 and/or an intermediate circuit capacitor 13 arranged in DC circuit 5 from being overcharged when the electric machine 3 is in generator operation or in a recuperation operation of a motor vehicle comprising the electric drive arrangement 1, electrical energy generated by the electric machine 3 can be transmitted to the resistor 4 via the switching device 11 of the inverter device 2, and there be converted into heat. In particular, excess electrical energy which is generated by the electric machine 3, i.e., electrical energy that can no longer be accommodated in the energy store 6 and/or the intermediate circuit capacitor 13, can be converted into heat due to the parallel connection of the resistor 4 to the DC side of the inverter circuit 10 in the resistor 4 when the switching device 11 is closed. Due to the fact that resistor 4 is connected in parallel with the energy store 6 and/or with the intermediate circuit capacitor 13, energy store 6 and intermediate circuit capacitor 13 can also be discharged via resistor 4.

For this purpose, the control device 12 is designed to control the switching device 11 for energizing the resistor 4 in a brake chopper operation. The control device 12 can activate the switching device 11 in an open-loop or closed-loop control process for the targeted energizing of the resistor 4 and, in particular, can connect the resistor via the switching device 11 to the DC circuit 5 or the DC side of the inverter circuit 10 and disconnect it again in quick succession. Furthermore, the control device 12 also enables the operation of the inverter circuit 10 for operating the electric machine 3, in particular in motor operation and in generator operation. The structure of the inverter circuit 2 is explained in more detail below with reference to FIG. 2.

FIG. 2 shows an exemplary embodiment of the design of an inverter device 2. In this exemplary embodiment, the control device 12 comprises a printed circuit board 14 on which a first driver circuit 15, a second driver circuit 16, and a control unit 17 are arranged. The switching elements of the inverter circuit 10 are driven by the first driver circuit 15. The switching elements of the inverter circuit 10 can be, for example, power switching elements such as insulating gate transistors or metal oxide semiconductor field-effect transistors. The switching elements can be implemented, for example, in the form of power modules, for example as half-bridge modules. In the case of a three-phase electric machine 3, for example, the inverter circuit 10 can comprise three half-bridge modules and thus six power switching elements. Correspondingly, the first driver circuit 15 can have six gate drivers.

The second driver circuit 16 is designed to control the switching device 11. The switching device 11 can also have one or more power switches such as a bipolar transistor with an insulating gate and/or a metal oxide semiconductor field-effect transistor. It is possible, for example, for the switching device 11 to have a first switching element 18 and a second switching element 19, with which one of the terminals of the resistor 4 can be connected to the DC circuit 5 in each case. The provision of two switching elements 18, 19 increases the reliability since the resistor 4 is not unintentionally energized from the DC circuit 5 in the event of a failure of a single switching element.

It is also possible for the switching device 11 to comprise more than two switching elements 18, 19 in order, as indicated by dashed lines, to also connect a multi-phase resistor 4 to the DC circuit 5. A multi-phase resistor 4 can have, for example, one or more, in particular asymmetrical, center taps, with which different resistance values can be tapped between different terminals of the resistor 4 and connected to the DC circuit 5. In this way, different resistance values of the resistor 4 can be connected to the DC circuit 5 or the DC side of the inverter circuit 10, for example as a function of an electrical power to be converted into heat via the resistor 4. For this purpose, the multiple power switching elements 18, 19 of the switching device 11 can form at least one half-bridge and/or at least one full-bridge, for example, which can be connected to the two or more terminals of a single-phase or multi-phase resistor 4. The power classes of the switching elements 18, 19 can be adapted to the maximum power that can be transmitted to the resistor 4 so that in particular the maximum power that can be generated by the electric machine 3 can also be transmitted to the resistor 4.

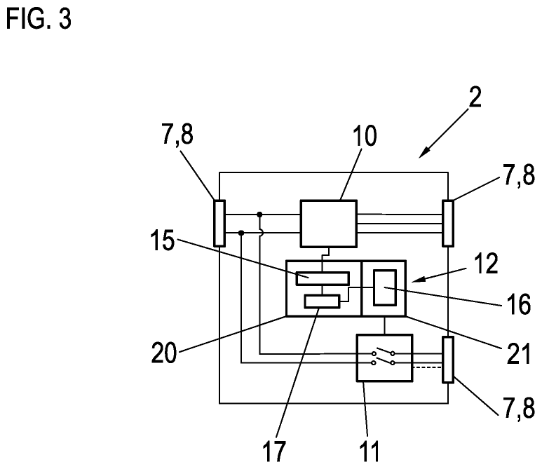

FIG. 3 shows an exemplary embodiment of an inverter device 2. In this exemplary embodiment, the control device 12 comprises a first printed circuit board 20 and a second printed circuit board 21, which is connected to the first printed circuit board 20. The first printed circuit board 20 and the second printed circuit board 21 can be mechanically and electrically connected, for example, via a plug connection and/or via at least one cable. In particular, the second driver circuit 16, which is arranged on the second printed circuit board 21, is electrically connected to the control unit 17 on the first printed circuit board 20 so that the second driver circuit 16 can also be operated via the control unit 17. This makes it possible for the control device 12 to be constructed in a modular manner and, in the case of the integration of a brake chopper in the inverter device 1 or the possibility of connecting an electrical resistor 4 to a switching device 11 of the inverter device 2, to be designed accordingly for actuating the switching device 11.

In both exemplary embodiments, it is advantageously possible to operate both the inverter device 10 and the switching device 11 via the control device 12. This reduces the effort involved in producing the inverter device 2, since it has only a single control device 12, which has to be checked or released. Furthermore, it is advantageously possible in both exemplary embodiments that the inverter circuit 10 or the power switching elements of the inverter circuit 10 and the switching device 11 or the power switching elements of the switching device 11 can be arranged on a common housing surface of the housing 9. In this way, it is possible to cool, in particular, the power switching elements of the switching device 11 and the inverter circuit 10 via a common cooling device.

Additionally or alternatively to the connection to a housing surface of the housing 9, the inverter circuit 10 and the switching device 11 can also be arranged on a common cooling body, for example a cooling plate. A cooling of the inverter device 2 can be cooled via a heat sink attached to a housing side, for example a thermally coupled cooling circuit or the like.

The representation of the terminals 8 of the connection device 7 in the exemplary embodiments described is purely schematic; the terminals 8 can also be arranged at other positions on the housing 9. A different combination of the terminals 8 is also possible.

### LIST OF REFERENCE SYMBOLS

1 Drive assembly
2 Inverter device
3 Electric machine
4 Resistor
5 DC circuit
6 Stored energy source
7 Connection device
8 Terminal
9 Housing
10 Inverter circuit
11 Switching device
12 Control device
13 Intermediate circuit capacitor
14 Printed circuit board
15 First driver circuit
16 Second driver circuit
17 Control unit
18 Switching element
19 Switching element
20 First printed circuit board
21 Second printed circuit board

1. An inverter device comprising a connection device and a housing in which an inverter circuit, a switching device, and a control device are accommodated, wherein the inverter circuit is connected to a direct current circuit and to an electric machine via the connection device, and the switching device is connected to the DC circuit and to a resistor via the connection device, the inverter circuit is actuated by the control device to operate the electric machine, and the switching device is actuated by the control device to selectively energize one of the resistor or the DC circuit via the inverter circuit.

2. The inverter device according to claim 1, wherein the control device is configured to actuate the switching device to energize the resistor in a brake chopper operation.

3. The inverter device according to claim 1, wherein the control device has a first driver circuit for configured to actuate the inverter circuit, a second driver circuit configured to actuate the switching device and a control unit, wherein the control unit is configured actuate the first driver circuit and the second driver circuit.

4. The inverter device according to claim 3, wherein the first driver circuit, the second driver circuit, and the control unit are arranged on a common printed circuit board.

5. The inverter device according to claim 3, wherein the first driver circuit and the control unit are arranged on a first printed circuit board, and the second driver circuit is arranged on a second printed circuit board wherein the first printed circuit board and the second printed circuit board are connected to each other.

6. The inverter device according to claim 1, wherein the resistor is a single-phase resistor.

7. The inverter device according to claim 1, wherein the switching device has at least one power switching element.

8. The inverter device according to claim 7, wherein the switching device has multiple power switching elements, wherein the power switching elements form at least one of a half-bridge or a full-bridge.

9. The inverter device according to claim 1, wherein the inverter circuit and the switching device are arranged together on a common side of the housing.

10. An electric drive arrangement, comprising:
an electric machine;
a resistor;
a direct current (DC) circuit; and
an inverter device including:
a connection device having a housing;
an inverter circuit connected to the DC circuit and the electric machine via the connection device; and
a switching device connected to the DC circuit and the resistor via the connection device; and
a control device configured to actuate the inverter circuit to operate the electric machine and to actuate the switching device to selectively energizing one of the resistor or the DC circuit via the inverter circuit;
wherein the inverter circuit, the switching device, and the control device are each arranged within the housing.

11. The inverter device according to claim 1, wherein the inverter circuit and the switching device are arranged on a common cooling device.

12. The inverter device according to claim 6, wherein the resistor is a multi-phase resistor.

13. The inverter device according to claim 1, wherein the DC circuit includes an electric energy store, the resistor being connected in parallel with the electrical energy store via the connection device.

14. The electric drive arrangement according to claim 10, wherein the control device is configured to actuate the switching device to energize the resistor in a brake chopper operation.

15. The electric drive arrangement according to claim 10, wherein the control device has a first driver circuit configured to actuate the inverter circuit, a second driver circuit configured to actuate the switching device and a control unit, wherein the control unit is configured to selectively actuate the first driver circuit and the second driver circuit.

16. The electric drive arrangement according to claim 15, wherein the first driver circuit, the second driver circuit, and the control unit are arranged on a common printed circuit board.

17. The electric drive arrangement according to claim 15, wherein the first driver circuit and the control unit are arranged on a first printed circuit board, and the second driver circuit is arranged on a second printed circuit board, wherein the first printed circuit board and the second printed circuit board are connected to each other.

18. The electric drive arrangement according to claim 10, wherein the DC circuit includes an electric energy store, the resistor being connected in parallel with the electrical energy store via the connection device.

19. The electric drive arrangement according to claim 10, wherein the inverter circuit and the switching device are arranged together on a common side of the housing.

20. The electric drive arrangement according to claim 10, wherein the inverter circuit and the switching device are arranged on a common cooling device.
